(19) United States
(12) Patent Application Publication
(10) Pub. No.: US 2023/0361761 A1
(43) Pub. Date: Nov. 9, 2023

(54) FREQUENCY MULTIPLIER CIRCUIT

(71) Applicant: Paragraf Limited, Somersham (GB)

(72) Inventors: Ivor GUINEY, Somersham (GB); Thomas James BADCOCK, Somersham (GB); Robert WALLIS, Somersham (GB)

(73) Assignee: Paragraf Limited, Somersham (GB)

(21) Appl. No.: 18/143,854

(22) Filed: May 5, 2023

(30) Foreign Application Priority Data
May 6, 2022 (GB) 2206637.7

(51) Int. Cl. H03B 19/14; H03K 5/00

(52) U.S. Cl. CPC H03K 5/00006; H03B 19/14

(57) ABSTRACT

According to a first aspect of the disclosure, an integrated frequency multiplier circuit is provided. The circuit comprises a substrate, a strip of graphene, first and second electrode, a dielectric layer, a frequency input electrode, and a frequency output electrode. The strip of graphene has a uniform width provided on the substrate, the strip having a width x and a length y extending from a first end to a second end. The first and second electrodes are provided in electrical contact with the strip of graphene at the first and second ends of the strip of graphene respectively. The dielectric layer is provided on the strip of graphene, wherein the dielectric layer is provided across the width x of the strip of graphene. The frequency input electrode is formed on the dielectric layer, wherein the frequency input electrode is provided across the width x of the strip of graphene. The frequency input electrode is provided over the strip of graphene at a location closer to the first end of the strip of graphene than the second end. The frequency output electrode is provided in electrical contact with the strip of graphene at a location along the length of the strip of graphene between the second electrode and the frequency input electrode, spaced apart from the second electrode.

### FIELD OF THE DISCLOSURE

The present disclosure relates to circuits for changing the frequency of an AC waveform. In particular, the present disclosure relates to such circuits comprising graphene.

### BACKGROUND

AC/DC converters are electrical circuits which are used to convert an AC voltage into a DC voltage. A wide range of circuits are known for such an application including passive circuits and active circuits. Active circuits incorporate one or more switched devices (e.g. a transistor), while passive circuits are typically formed from diodes (e.g. a bridge circuit). The choice of circuit type (active or passive) may depend on the desired application of the AC/DC converter (e.g. signal power) and any other design considerations such as they physical weight of the device, the physical size of the device, operating temperature etc.

Two-dimensional (2D) materials, in particular graphene, are currently the focus of intense research and development worldwide. 2D-materials have been shown to have extraordinary properties, both in theory and in practice which has led to a deluge of products incorporating such materials which include coatings, batteries and sensors to name but a few. Graphene is most prominent and is being investigated for a range of potential applications. Most notable is the use of graphene in electronic devices and their constituent components and includes transistors, LEDs, photovoltaic cells, Hall-effect sensors, diodes and the like.

Due to the high carrier mobility of graphene (typically in excess of 10,000 cm²/Vs), active circuit incorporating one or more graphene devices have been developed. For example, “Graphene-Based Frequency Tripler” Chen et al, Nano Letter, 2012, vol. 12, pages 2067-2070, 2012 discloses a graphene based frequency tripler. The device comprises two graphene FETs connected in series.

Against this background, it is an object of the invention to provide an improved, or at least commercially useful alternative, frequency multiplier circuit.

### SUMMARY

According to a first aspect of the disclosure, an integrated frequency multiplier circuit is provided. The circuit comprises a substrate, a strip of graphene, first and second electrodes, a dielectric layer, a frequency input electrode, and a frequency output electrode. The strip of graphene has a uniform width provided on the substrate, the strip having a width x and a length y extending from a first end to a second end. The first and second electrodes are provided in electrical contact with the strip of graphene at the first and second ends of the strip of graphene respectively. The dielectric layer is provided on the strip of graphene, wherein the dielectric layer is provided across the width x of the strip of graphene. The frequency input electrode is formed on the dielectric layer, wherein the frequency input electrode is provided across the width x of the strip of graphene. The frequency input electrode is provided over the strip of graphene at a location closer to the first end of the strip of graphene than the second end. The frequency output electrode is provided in electrical contact with the strip of graphene at a location along the length of the strip of graphene between the second electrode and the frequency input electrode, spaced apart from the second electrode.

Accordingly, the circuit of the first aspect provides an active frequency multiplier circuit wherein the active device comprises graphene. In essence, the frequency input electrode acts as a gate for a graphene FET formed in the strip of graphene. The strip of graphene also includes a portion of its length provided between the frequency output electrode and the second electrode. Such a length allows the strip of graphene to also act as a resistor formed between the second electrode and the frequency output electrode/graphene FET of the circuit. As such, the circuit of the first aspect integrates both a graphene FET and a graphene resistor into a single strip of graphene. It will be appreciated that such integration provides for a circuit which is lightweight (the resistor and FET both comprising graphene) relative to frequency multiplier circuits formed from other semiconducting materials.

In some embodiments, the frequency output electrode is equally spaced from the first and second electrodes along the strip of graphene. As such, the length of the strip of graphene between the frequency output electrode and the first electrode (effectively the length of the channel of the graphene FET) is the same as the length of the strip of graphene between the frequency output electrode and the second electrode (i.e. the length of the resistor). As such, the channel region has a nominal resistance that is about the same as the resistance of the resistor. By balancing the resistances of the two devices (the resistor and the FET), the frequency multiplier circuit has improved frequency multiplication properties.

In some embodiments, the graphene sheet may have a sheet resistance of at least: 250 Ω/sq, 500 Ω/sq, or 1 kΩ/sq. In some embodiments, the graphene sheet may have a sheet resistance of no greater than 10 kΩ/sq. By providing the graphene sheet with such a sheet resistance, a frequency multiplier circuit may be provided with a desired operating frequency. In effect, the resistance provided by the graphene sheet between the second electrode and the frequency multiplier output electrode may be selected based on the length of the graphene sheet. For example, in some embodiment the resistance of the graphene sheet between the second electrode and the frequency multiplier output electrode may be at least: 250 Ω, 500 Ω, or 1 kΩ. In some embodiments, the resistance of the graphene sheet between the second electrode and the frequency multiplier output electrode may be no greater than 50 kΩ.

In some embodiments, the first and second electrodes are each provided on the substrate adjacent to the strip of graphene such that each of the first and second electrodes are in direct contact with a respective edge of the strip of graphene. As such, the first and second electrodes each form direct electrical connection to the strip of graphene via an edge of the strip of graphene. Such a contact method provides for improved charge carrier injection into the strip of graphene. Furthermore, by providing the electrodes adjacent to the strip of graphene, rather than overlapping the graphene, doping of the graphene from the first and second electrodes (e.g. metal doping) can be reduced or eliminated.

In some embodiments, the graphene sheet is preferably provided on a non-metallic surface of a substrate. For example, the non-metallic surface may be an electrically insulative surface (for example, a substrate may be a silicon substrate having a silicon dioxide surface). The substrate may also be a CMOS wafer which may be silicon-based and have associated circuitry embedded within the substrate. A substrate may also comprise one or more layers. In another example, a substrate may comprise a non-metallic layer which provides a non-metallic growth surface, and a conductive layer (for example, silicon on insulator (SOI) substrates such as a silicon substrate having a silicon oxide layer). The conductive layer can serve as a contact for electronic devices

Preferably, the non-metallic surface upon which the graphene layer structure is provided is silicon (Si), silicon carbide (SiC), silicon nitride (Si₃N₄), silicon dioxide (SiO₂), sapphire (Al₂O₃), aluminium gallium oxide (AGO), hafnium dioxide (HfO₂), zirconium dioxide (ZrO₂), yttria-stabilised hafnia (YSH), yttria-stabilised zirconia (YSZ), magnesium aluminate (MgAl₂O₄), yttrium orthoaluminate (YAIO₃), strontium titanate (SrTiO₃), cerium oxide (Ce₂O₃), scandium oxide (Sc₂O₃), erbium oxide (Er₂O₃), magnesium difluoride (MgF₂), calcium difluoride (CaF₂), strontium difluoride (SrF₂), barium difluoride (BaF₂), scandium trifluoride (ScF₃), germanium (Ge), hexagonal boron nitride (h-BN), cubic boron nitride (c-BN) and/or a III/V semiconductor such as aluminium nitride (AIN) and gallium nitride (GaN). Preferably, the substrate comprises silicon, silicon nitride, silicon dioxide, sapphire, aluminium nitride, YSZ, germanium and/or calcium difluoride. In some embodiments, the substrate may consist of one such material.

In some embodiments, the dielectric layer comprises an inorganic oxide, nitride, carbide, fluoride or sulphide, preferably alumina or silica.

In some embodiments, the length y of the strip of graphene may be at least 5 mm, although shorter devices may be provided. In some embodiments, the length y of the strip of graphene is no greater than 20 mm. In some embodiments, the width x of the strip of graphene is at least 1 mm, although other widths may be provided. In some embodiments, the width x of the strip of graphene is no greater than 10 mm. In some embodiments, the strip of graphene is generally rectangular. As such, the strip of graphene may be provided with a desired length and/or width in order to control the resistance of the channel of the FET and the resistance of the resistor.

In some embodiments, the length y of the strip of graphene may be defined relative to the width w of the strip of graphene by an aspect ratio (y/x). The aspect ratio of the strip of graphene may be used to provide the desired resistance of the FET and resistor. In some embodiments, the aspect ratio may be at least 0.5. In some embodiments, the aspect ratio may be no greater than 20. By following such aspect ratios, devices of different lengths may be provided, in particular devices having a length of less than 5 mm.

In some embodiments, the location of the frequency output electrode on the strip of graphene and a sheet resistance of the graphene is provided such that a resistance of the strip of graphene between the frequency output electrode and the second electrode is at least: 250 Ω, 500 Ω or 1 kΩ, and/or no greater than 50 kΩ.

In some embodiments, the strip of graphene extending between the frequency output electrode and the second electrode which acts as a resistance may be provided as a variable resistance in order to allow the frequency response of the circuit to be controllable. As such, in some embodiments the integrated frequency multiplier circuit may further comprise a resistance dielectric layer provided on the strip of graphene, wherein the resistance dielectric layer is provided across the width x of the strip of graphene and between the frequency output electrode and the second end of the strip of graphene. The circuit may also comprise a variable resistance electrode provided on the resistance dielectric layer, wherein the variable resistance dielectric layer is provided across the width x of the strip of graphene. As such, a variable resistance electrode may be provided to modulate the resistance of the graphene sheet between the frequency output electrode and the second electrode by application of a suitable voltage to variable resistance electrode. Consequently, the resistance of the graphene sheet may be controlled through application of an appropriate voltage. Such voltage control may be utilised to improve the operation of the frequency multiplier circuit under different temperatures. In some embodiments, the voltage control may be utilised to control the frequency response of the integrated frequency multiplier circuit.

According to a second aspect of the disclosure, an AC to DC current converter circuit is provided. The AC to DC current converter circuit comprises a frequency multiplier circuit according to the first aspect, and a capacitor connected between the frequency output electrode and the first electrode formed at the first end of the graphene strip. As such, the frequency multiplier circuit of the first aspect may be further adapted to perform AC to DC current conversion. As such, an AC to DC current converter may be provided incorporating the integrated graphene FET and graphene resistor of the first aspect.

In some embodiments, the capacitor is formed on the substrate, and the AC to DC current converter circuit further comprises: a third electrical contact extending between the frequency output electrode and a first terminal of the capacitor; and a fourth electrical contact extending between the second electrode and a second terminal of the capacitor. Thus, the AC to DC current converter circuit may be formed on a single substrate. By providing the capacitor, resistor, and transistor of the AC to DC current circuit on a single substrate, the circuit may be formed in an economic and space efficient manner.

In some embodiments, the capacitor may comprise a first terminal and a second terminal, wherein the first and second terminals are separated by a capacitor dielectric layer. For example, in some embodiments, the capacitor dielectric layer may be formed from the same material as the dielectric layer which is formed on the strip of graphene. By forming the capacitor using a dielectric material which is also being utilised in other parts of the AC to DC current converter circuit, the (dielectric) capacitor may be formed concurrently with other parts of the circuit. Thus, the AC to DC current converter circuit may be formed in an efficient and economical manner.

In some embodiments, the capacitor is a graphene capacitor. In some embodiments, the graphene capacitor comprises: a first set of graphene fingers provided on the substrate; and a second set of graphene fingers provided on the substrate. The first and second sets of graphene fingers are provided on the substrate such that the first and second sets of graphene fingers are interdigitated. As such, the graphene capacitor has a planar design on the substrate. Furthermore, in some embodiments the resistor, transistor and capacitor of the AC to DC circuit may each be formed from graphene. For example, in some embodiments the graphene capacitor may be formed on the substrate using the same patterning process used to form the strip of graphene. Such a circuit may be efficient and economical to manufacture.

According to a third aspect of the disclosure, a method of forming a monolithic frequency multiplier circuit is provided. The method comprises:
depositing a graphene layer on a substrate using a chemical vapour process;
patterning the graphene layer to define a strip of graphene, the strip having a width x and a length y extending from a first end to a second end;
forming first and second electrodes in electrical contact with the strip of graphene at the first and second ends respectively;
forming a dielectric layer on the strip of graphene, the dielectric layer extending across the width of the strip of graphene and along a portion of the length of the strip towards the second end;
forming a frequency input electrode on the dielectric layer, the frequency input electrode provided across the width x of the strip of graphene, wherein the frequency input electrode is closer to the first end of the strip of graphene than the second end;
forming a frequency output electrode in electrical contact with the strip of graphene at a location along the length of the strip of graphene between the second electrode and the frequency input electrode and spaced apart from the second electrode.

As such, the method of the third aspect may be used to form a frequency multiplier circuit according to the first aspect of the disclosure.

According to a fourth aspect of the disclosure, a method of forming an AC to DC current converter circuit is provided. The method comprises:
depositing a graphene layer on a substrate using a chemical vapour process;
patterning the graphene layer to define a strip of graphene, the strip having a width x and a length y extending from a first end to a second end;
forming first and second electrodes in electrical contact with the strip of graphene at the first and second ends respectively;
forming a dielectric layer on the strip of graphene, the dielectric layer extending across the width of the strip of graphene and along a portion of the length of the strip towards the second end;
forming a frequency input electrode on the dielectric layer, the frequency input electrode provided across the width x of the strip of graphene, wherein the frequency input electrode is closer to the first end of the strip of graphene than the second end;
forming a frequency output electrode in electrical contact with the strip of graphene at a location along the length of the strip of graphene between the second electrode and the frequency input electrode and spaced apart from the second electrode; and
providing a capacitor in electrical contact between the frequency output electrode and the first electrode formed at the first end of the graphene strip.

As such, the method of the fourth aspect may be used to form a frequency multiplier circuit according to the first aspect of the disclosure.

In some embodiments, providing the capacitor comprises depositing a further graphene layer on a substrate using a chemical vapour process, and patterning the graphene layer to define a first set of graphene on the substrate and a second set of graphene fingers on the substrate, wherein the first and second sets of graphene fingers are interdigitated. In some embodiments, the further graphene layer may be deposited using the same deposition process used to deposit the graphene layer used to form the strip of graphene. Similarly, the patterning step used to define the first and second sets of graphene fingers may be performed at the same time as the patterning step used to define the strip of graphene. As such, the graphene capacitor may be formed at the same time (i.e. with the same processing steps) used to form the graphene strip.

### BRIEF DESCRIPTION OF THE DRAWINGS

Embodiments of the disclosure will now be described, by way of example only, with reference to accompanying figures in which:

FIG. 1 shows a schematic diagram of a frequency multiplier circuit according to an embodiment of the disclosure;

FIG. 2 is a graph of a source-drain current response of a frequency multiplier circuit according to an embodiment of the disclosure;

FIG. 3 is a graph depicting the frequency multiplication of a 0.5 Hz input wave using a frequency multiplier circuit according to an embodiment of the disclosure;

FIG. 4 shows a schematic diagram of an AC to DC converter circuit according to an embodiment of the disclosure; and

FIG. 5 is a block diagram of a method of forming an integrated frequency multiplier circuit or an AC to DC converter according to this disclosure.

### DETAILED DESCRIPTION

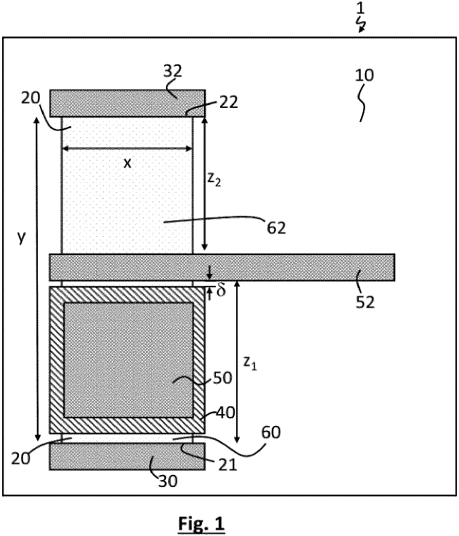

According to a first embodiment of the disclosure, an integrated frequency multiplier circuit 1 is provided. The integrated frequency multiplier circuit 1 comprises a substrate 10, a strip of graphene 20, a first electrode 30, a second electrode 32, a dielectric layer 40, a frequency input electrode 50, and a frequency output electrode 52. A schematic diagram showing a plan view of the integrated frequency multiplier circuit 1 is shown in FIG. 1.

As will be explained in further detail below, the integrated frequency multiplier circuit provides a transistor element and a resistor element which are interconnected in order to provide a frequency multiplication functionality. According to the first embodiment, the transistor element and the resistor element each comprise graphene.

The substrate 10 may comprise a non-metallic surface on which the other layers of the integrated frequency multiplier circuit 1 are provided. Preferably, the surface is an electrically insulative surface (for example, a substrate may be a silicon substrate having a silicon dioxide surface). The substrate 10 may also be a CMOS wafer which may be silicon based and have associated circuitry embedded within the substrate. A substrate 10 may also comprise one or more layers (for example, regions or channels of embedded waveguide materials such as silicon nitride suitable for EOMs). In another example, a substrate may comprise a non-metallic layer which provides a non-metallic growth surface, and a conductive layer (for example, silicon on insulator (SOI) substrates such as a silicon substrate having a silicon oxide layer). The conductive layer can serve as a contact for electronic devices.

Preferably, the non-metallic surface upon which the graphene layer structure is provided is silicon (Si), silicon carbide (SiC), silicon nitride (Si₃N₄), silicon dioxide (SiO₂), sapphire (Al₂O₃), aluminium gallium oxide (AGO), hafnium dioxide (HfO₂), zirconium dioxide (ZrO₂), yttria-stabilised hafnia (YSH), yttria-stabilised zirconia (YSZ), magnesium aluminate (MgAl₂O₄), yttrium orthoaluminate (YAIO₃), strontium titanate (SrTiO₃), cerium oxide (Ce₂O₃), scandium oxide (Sc₂O₃), erbium oxide (Er₂O₃), magnesium difluoride (MgF₂), calcium difluoride (CaF₂), strontium difluoride (SrF₂), barium difluoride (BaF₂), scandium trifluoride (ScF₃), germanium (Ge), hexagonal boron nitride (h-BN), cubic boron nitride (c-BN) and/or a III/V semiconductor such as aluminium nitride (AIN) and gallium nitride (GaN). In some embodiments, the substrate 10 may comprise sapphire or silicon, particularly for graphene prepared by the method of WO 2017/029470. Where the substrate 10 comprises sapphire, in some embodiments it is preferable that the sapphire is R-plane sapphire. As is known in the art, r-plane refers to the crystallographic orientation of the surface of the substrate (i.e. the surface upon which graphene is deposited). Such a substrate is particularly suited to providing high quality graphene which is well suited to the formation of the graphene strip 20 according to this disclosure. In part, this is due to effect of the substrate 10 on the resulting charge carrier density of the graphene deposited thereon. For example, graphene strips 20 according to this disclosure may preferably have a charge carrier density in the range of 5 × 10¹¹ cm-² to 1 × 10¹⁴ cm⁻².

The strip of graphene 20 is formed on the substrate 10. The strip of graphene 20 has a uniform width provided on the substrate. As such, the strip of graphene 20 has a generally rectangular shape (including square shapes) formed on the substrate 10.

In the embodiment of FIG. 1, the strip of graphene has a width x and a length y extending from a first end 21 to a second end 22. In some embodiments, the length y of the strip of graphene 20 is at least: 5 mm, or 7 mm or 10 mm.

In some embodiments, the length y of the strip of graphene 20 may be no greater than: 20 mm, or 17 mm, or 15 mm. The length y of the strip of graphene 20 may be selected in order to provide a desired channel resistance for the transistor, and/or a desired resistance for the resistor.

In some embodiments, the width x of the strip of graphene is at least: 1 mm, 2 mm, 3 m, or 5 mm. In some embodiments, the width x of the strip of graphene 20 is no greater than: 10 mm, 9 mm, 8 mm, or 7 mm. The width x and length y of the strip of graphene 20 may be selected in combination in order to provide a desired channel resistance for the transistor, and/or a desired resistance for the resistor.

In some embodiments, the strip of graphene 20 may have a sheet resistance of at least 250 Ω, 500 Ω, or 1 kΩ/sq. In some embodiments, the strip of graphene 20 may have a sheet resistance of no greater than 10 kΩ/sq. The sheet resistance of the strip of graphene 20 may be controlled according to the carrier density of the strip of graphene. As such, the sheet resistance of the strip of graphene 20 may be selected in order to provide the resistor section of the integrated frequency response circuit with the desired resistance.

The strip of graphene 20 may be formed from a layer of graphene which is deposited as a continuous layer across substantially all of the substrate 10. As such, the strip of graphene 20 may be synthesised directly on the substrate 10 and therefore does not involve any physical transfer steps. The strip of graphene 20 may then be formed having the desired length y and width x using a patterning step. As such, direct synthesis of the graphene layer as a continuous layer is preferable as it allows the strip of graphene 20 to be subsequently patterned and etched in a reliable and economic manner.

Preferably the graphene layer is formed by Chemical Vapour Deposition (CVD) or MOCVD growth. It is particularly preferable that the graphene is formed by VPE or MOCVD. MOCVD is a term used to describe a system used for a particular method for the deposition of layers on a substrate. While the acronym stands for metal-organic chemical vapour deposition, MOCVD is a term in the art and would be understood to relate to the general process and the apparatus used therefor and would not necessarily be considered to be restricted to the use of metal-organic reactants or to the production of metal-organic materials but would simply require the use of a carbon containing precursor when forming graphene. Instead, the use of this term indicates to the person skilled in the art a general set of process and apparatus features. MOCVD is further distinct from CVD techniques by virtue of the system complexity and accuracy. While CVD techniques allow reactions to be performed with straight-forward stoichiometry and structures, MOCVD allows the production of difficult stoichiometries and structures. An MOCVD system is distinct from a CVD system by virtue of at least the gas distribution systems, heating and temperature control systems and chemical control systems. An MOCVD system typically costs at least 10 times as much as a typical CVD system. MOCVD is particularly preferred for achieving high quality graphene layer structures.

MOCVD can also be readily distinguished from atomic layer deposition (ALD) techniques. ALD relies on step-wise reactions of reagents with intervening flushing steps used to remove undesirable by products and/or excess reagents. It does not rely on decomposition or dissociation of the reagent in the gaseous phase. It is particularly unsuitable for the use of reagents with low vapour pressures such as silanes, which would take undue time to remove from the reaction chamber. MOCVD growth of graphene is discussed in WO 2017/029470 which is incorporated by reference and provides the preferred method.

The method of WO 2017/029470 provides a chamber which has a plurality of cooled inlets arranged so that, in use, the inlets are distributed across the substrate and have a constant separation from the substrate. The flow comprising a precursor compound may be provided as a horizontal laminar flow or may be provided substantially vertically. Inlets suitable for such reactors are well known and include Planetary and Showerhead® reactors available from Aixtron®. Other suitable growth chambers include Turbodisc K-series or Propel® MOCVD systems available from Veeco® Instruments Inc.

The graphene layer may be patterned to form the strip of graphene 20 by masking and etching steps. Lithography may be used to mask a region of the layer of graphene on the substrate 10 with a mask layer (not shown). The mask layer may comprise a photoresist, or a dielectric layer, or any other suitable mask layer for a lithographic technique known in the art.

A subsequent etching step may then be provided to remove the uncovered regions of graphene from the substrate 10. For example at least one uncovered region of the graphene layer may be etched away to form at least one covered region of graphene layer (i.e. the strip of graphene 20 plus the mask layer above). The mask layer may then be selectively removed from the strip of graphene 20 using a suitable lift of technique or selective etch (i.e. an etching process which does not etch the underlying strip of graphene 20).

Plasma etching is a typical process used in the manufacture of electronic devices and integrated circuits. Plasma etching involves the flow of a plasma of an appropriate gas mixture across the substrate, the plasma having been formed from application of an RF across two electrodes, typically under low pressure. In oxygen plasma etching, the RF radiation ionises the gas to form oxygen radicals which etch the layer structure. The byproducts, also known in the art as “ash”, are removed by a pump which are predominantly carbon monoxide and carbon dioxide when a graphene layer structure is etched by oxygen plasma etching. In a preferred embodiment, the plasma etching comprises oxygen plasma etching. In a preferred embodiment, oxygen plasma etching comprises using at least 5 W RF power, preferably at least 10 W and more preferably at least 20 W, and preferably less than 200 W, preferably less than 100 W. The flow rate of O2 may be at least 1 sccm, preferably at least 3 sccm and/or less than 50 sccm, preferably less than 30 sccm. Preferably, the chamber pressure is at least 0.1 mbar and/or at most 100 mbar, preferably at least 0.2 mbar and/or at most 10 mbar. Accordingly, the time required for plasma etching may be as little as 1 second and/or up to 5 minutes. Preferably, the time required is at least 10 seconds and/or less than 2 minutes.

The first and second electrodes 30, 32 are provided in electrical contact with the strip of graphene 20 at the first and second ends 21, 22 of the strip of graphene 20 respectively. As shown in FIG. 1, each of the first and second electrodes 30, 32 extend across the entire width x of the strip of graphene 20. As shown in FIG. 1, each of the first and second electrodes 30, 32 may have a generally rectangular shape, although other shapes may also be provided. In FIG. 1, each of first and second electrodes may extend away from the strip of graphene 20 in order to form electrical connections to other circuits or components.

Each of the first and second electrodes 30, 32 are provided in direct electrical contact with the first and second ends 21, 22 of the strip of graphene 20 in order to provide improved current injection into the strip of graphene 20. In the embodiments of FIG. 1, each of the first and second electrodes 30, 32 form Ohmic contacts with the strip of graphene 20. Preferably each of the first and second electrodes comprises one or more of titanium, aluminium, chromium and gold. Preferably, the first and second electrodes 30, 32 are titanium and/or gold electrodes. The first and second electrodes 30, 32 may be formed by any standard technique such as electron beam deposition, preferably using a mask.

In the embodiment of FIG. 1, the first and second electrical contacts 30, 32 are provided adjacent to the first and second ends 21, 22 of the strip of graphene. As such, the strip of graphene extending between the first and second contacts 30, 32 has a length y.

The frequency output electrode 52 is provided in electrical contact with the strip of graphene at a location along the length of the strip of graphene 20. The frequency output electrode may be located at a location along the length of the strip of graphene between the second electrode and the frequency input electrode, spaced apart from the second electrode. As shown in FIG. 1, the frequency output electrode 52 extends across the width x of the strip of graphene, although in some embodiments, the frequency output electrode may not extend fully across the strip of graphene 20. The frequency output electrode 52 effectively divides the strip of graphene (having length y) into two regions. A first region 60 of the strip of graphene has a length z₁ and extends between the first end 21 and the frequency output electrode 52. In effect, the first region 60 provides a region of the strip of graphene in which the transistor is formed.

The second region 62 of the strip of graphene 20 having length z₂ extends between the second end 22 of the strip of graphene 20 and the frequency output electrode 52. The second region 62 of the strip of graphene 20 defines a resistor extending between the second electrode 32 and the frequency output electrode 52.

The frequency output electrode 52 is located in FIG. 1 in order to define the lengths z₁ and z₂ of the first and second regions 60, 62 respectively. In FIG. 1, the lengths z₁ and z₂ (and consequently the areas of the respective first and second regions 60, 62) are about the same.

Similar to the first and second electrodes, the frequency output electrode 52 may be formed by any standard technique such as electron beam deposition, preferably using a mask. The frequency output electrode 52 may comprise any suitable contact material configured to form an Ohmic contact to the strip of graphene 20. For example, titanium and/or gold electrodes may be used.

In some embodiments, the length z₁ of the first region 60 may be less than the length of the second region z₂ 62. As such, the length of the resistor (and the associated resistance of the resistor) may be greater than the resistance of the graphene strip in the first region 60 used to form the transistor. For example, the length z₁ of the first region 60 may be greater than 60% of the length z₂ of the second region 62 up to no greater than 100% of the length z₂ of the second region 62.

It will be appreciated that the length of the frequency output electrode 52 in the y direction of the graphene strip is non-zero as shown in FIG. 1. The area of the frequency output electrode 52 may be selected in order to provide the desired electrical contact conductivity to the graphene strip 20. The overall length y of the graphene strip may be selected in order to provide for the desired lengths z₁, z₂ of the first and second regions 60, 62 and the length of the frequency output electrode 52.

The second region 62 of the graphene strip defines a resistance for the integrated frequency multiplier circuit. The size of the resistance may be selected based on the dimensions for the second region (length z₂ and width x) and the sheet resistance of the graphene. In some embodiments, the second region 62 may define a resistance R between the second electrode 32 and the frequency output electrode of at least: 250 Ω, 500 Ω, or 1 kΩ. In some embodiments, the resistance R may be no greater than 50 kΩ.

As noted above, the first region 60 of the graphene strip provides a transistor functionality for the integrated frequency multiplier circuit 1. As shown in FIG. 1, the dielectric layer 40 is provided on the strip of graphene 20 in the first region 60. The dielectric layer 40 is provided across the width x of the strip of graphene. The dielectric layer 40 is provided in order to define a gate insulating layer for the transistor part of the integrated frequency multiplier circuit 1.

The dielectric layer 40 may comprise an inorganic oxide, nitride, carbide, fluoride or sulphide. In some preferred embodiments, the dielectric layer may comprise alumina or silica. The dielectric layer 40 may have a thickness (in a direction normal to the substrate 10) of at least 1 nm. The dielectric layer may have a thickness of no greater than 1000 nm. Preferably, the dielectric layer 40 is a continuous layer which is substantially free of pores, point defects and the like.

The dielectric layer 40, may be formed using any suitable process known in the art. For example, where the dielectric layer comprises alumina, the dielectric layer may be formed by a thermal evaporation technique, for example e-beam evaporation, or preferably formed by an Atomic Layer Deposition (ALD) technique. Forming the dielectric layer by thermal evaporation provides for the formation of the dielectric layer on the strip of graphene 20 without damaging the graphene sheet.

ALD is technique known in the art and comprises the reaction of at least two precursors in a sequential, self-limiting manner. Repeated cycles to the separate precursors allow the growth of a thin film of the dielectric layer in a conformal manner (i.e. uniform thickness across graphene strip 20) due to the layer by layer growth mechanism. Alumina is a particularly preferred dielectric material and can be formed by sequential exposure to trimethylaluminium (TMA) and an oxygen source, preferably one or more of water (H2O), O2, and ozone (O3), preferably water.

The frequency input electrode 50 is formed on the dielectric layer 40, wherein the frequency input electrode 50 is provided across the width x of the strip of graphene 20. As such, the frequency input electrode 50 is provided over the first region 60 of the strip of graphene. The frequency input electrode 50 is provided over the strip of graphene 20 at a location closer to the first end 21 of the strip of graphene 20 than the second end 22 (i.e. on the first region of the graphene strip 20).

The frequency input electrode 50 can be formed by any standard technique such as electron beam deposition, preferably using a mask on the dielectric layer. For example, the frequency input electrode may comprise gold or titanium contacts. In some embodiments, the frequency input electrode 50 may comprise a plurality of layers. For example, in some embodiments, the frequency input electrode 50 may comprise a bi-layer combination of Ti and Au, Al and Ni, or any two of Pt, Pd, Ag and Au.

An electrical bias can be applied to the frequency input electrode 50 in order to modulate the charge carriers within the graphene strip 20 below the frequency input electrode. As such, the frequency input electrode 50 in combination with the dielectric layer 40 defines a “top gate” structure of a Field Effect Transistor (FET), wherein the graphene strip 20 provides the “channel” layer of the FET.

One known property of graphene is that the mobility of the holes and the mobility of the electrons are approximately the same. Accordingly, a graphene FET-type device has an ambi-polar behaviour in which majority hole conduction can occur in the channel region when the device is under negative bias, and majority electron conduction can occur when the device is under positive bias. As bias is reduced towards 0 V (or a value shifted from 0 V in practice), charge carrier conduction is reduced towards a minimum point known as the Dirac point. Application of positive or negative bias about the Dirac point of a graphene FET causes an increase in current. This behaviour may be applied in order to provide frequency multiplication in the integrated frequency multiplier circuit of FIG. 1.

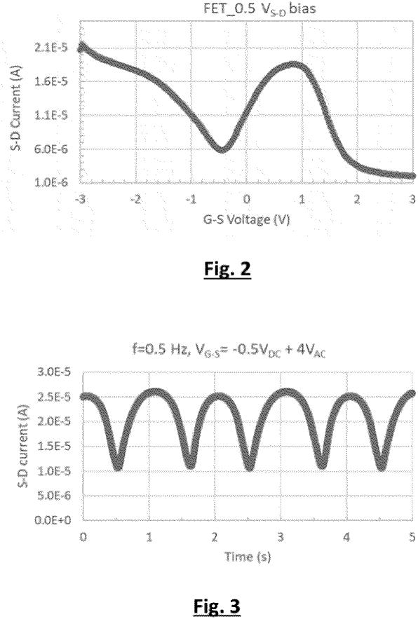

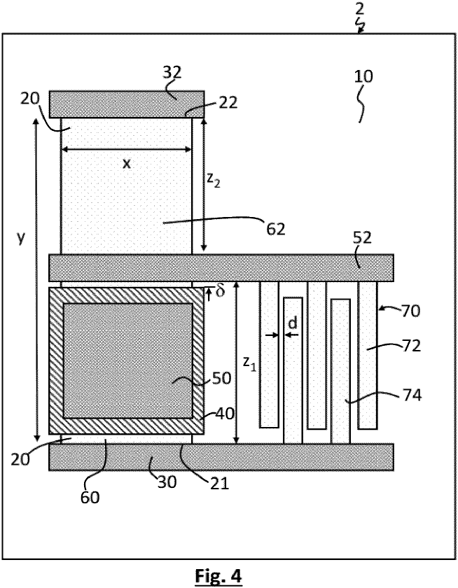

FIG. 2 shows a graph of the current (I_{SD}) flowing between the first and second electrodes 30, 32 of an integrated frequency multiplier circuit 1 according to this disclosure for a range of different voltages applied to the frequency input electrode 50. In the graph of FIG. 2, a voltage of 0.5 V is applied between the first and second electrodes 30, 32 (V_{SD}) for each measurement. As shown in FIG. 2, the Dirac point occurs at a frequency input voltage (V_{GS}) relative to the voltage applied to the first electrode 30, of about -0.5 V. Variation in the frequency input voltage V_{GS} about the Dirac point causes the current (I_{SD}) to increase in magnitude. As shown in FIG. 2, the current increases in an approximately linear manner on either side of the Dirac point over a range of +/- 1 V. Such a V_{GS} - I_{SD} behaviour can be used to perform frequency multiplication, for example as shown in FIG. 3.

FIG. 3 shows a current output of the integrated frequency multiplier circuit 1 from the frequency output electrode 52 in response to a 0.5 Hz AC input signal (V_{GS}) applied to the frequency input electrode 50. The input signal has a peak to peak amplitude of about 2 V, biased at about -0.5 V (i.e. biased to the Dirac point). As shown in FIG. 3, the integrated frequency multiplication circuit increases outputs a waveform which oscillates with a fundamental frequency of about 1 Hz (i.e. a frequency doubling).

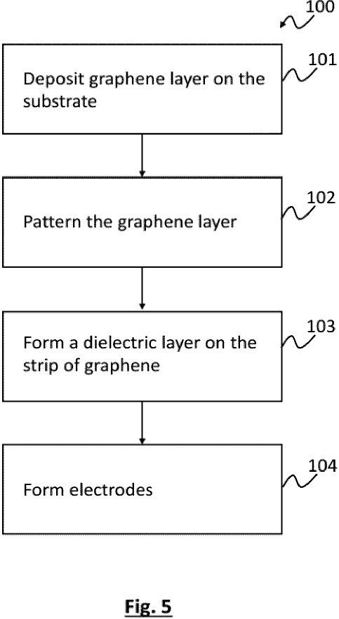

In some embodiments, the second region 62 of the strip of graphene 20 having length z₂ may be provided as a variable resistance. As such, in some embodiments, a resistance dielectric layer (not shown in FIGS. 1 or 4) may be provided on the strip of graphene 20, wherein the resistance dielectric layer is provided across the width x of the strip of graphene 20. The resistance dielectric layer may extend along at least some of the length y of the second region 62 of the strip of graphene. As such, the resistance dielectric layer is formed between the frequency output electrode 52 and the second end 22 of the strip of graphene 20. A variable resistance electrode (not shown in FIGS. 1 or 4) may be provided on the resistance dielectric layer, wherein the variable resistance dielectric layer is provided across the width x of the strip of graphene.

The variable resistance electrode may be provided to modulate the resistance of the graphene sheet underneath the variable resistance electrode by application of a suitable voltage to variable resistance electrode. Consequently, the resistance of the at least some of the graphene in the second region 62 of graphene sheet 20 may be controlled through application of an appropriate voltage to the variable resistance electrode. For example, a DC bias (e.g. a voltage of about no more than +/- 10 V) may be applied to the variable resistance electrode in order to modify the charge carrier density (and therefore the resistance) in the second region 62. Such voltage control may be utilised to improve the operation of the frequency multiplier circuit under different temperatures. In some embodiments, the voltage control may be utilised to control the frequency response of the integrated frequency multiplier circuit.

In some embodiments, the resistance dielectric layer and the variable resistance electrode may be formed using similar materials and processes as the dielectric layer 40 and the frequency input electrode 50 as described in further detail herein.

In some embodiments, the frequency multiplication functionality of the circuit 1 can be used to provide an AC to DC converter 2. FIG. 4 shows a schematic diagram of such a circuit, which incorporates the integrated frequency multiplier circuit 1 of the first embodiment. Components in FIG. 4 which are equivalent to the components of FIG. 1 are denoted with the same reference numerals.

The AC to DC converter circuit of FIG. 4 incorporates a capacitor 70. The capacitor 70 is connected between the frequency output electrode 52 and the first electrode 30. By including an energy storage element, rectified current waveforms (for example as shown in FIG. 3) may be smoothed out to provide a DC current.

In the embodiment of FIG. 4, the capacitor 70 may comprise a graphene capacitor formed on the substrate 10. The graphene capacitor may be formed from a first set of graphene fingers 72 and a second set of graphene fingers 74 which are interdigitated. As shown in FIG. 4, the first set of graphene fingers 72 are connect to the frequency output electrode 52 and extend towards the first electrode 30. The second set of graphene fingers 74 are connected to the first electrode 30 and extend towards the first set of graphene fingers 72. The first and second sets of graphene fingers 72, 74 extend in a generally parallel manner to each other.

As shown in FIG. 4, the first and second sets of graphene fingers are formed on the substrate 10. Each first finger 72 is spaced apart from adjacent second fingers 74 by a first spacing d. The first spacing d may be selected, in combination with the number of first and second fingers 72, 74 to define the capacitance of the capacitor.

In the embodiment of FIG. 4, the first set of graphene fingers 72 comprise three fingers and the second set of graphene fingers 74 comprises two fingers. In other embodiments, each of the first and second sets of graphene fingers 72, 74 may comprise at least 3, 5, 7, 10 or 15 fingers. As such, it will be appreciated that capacitance of the capacitor 70 may be selected based on the number of graphene fingers included, along with the spacing d.

The capacitor 70 may be connected to the frequency output electrode 52 by a third electrode extending between the frequency output electrode 52 and a first terminal of the capacitor. The capacitor may also be connected to the first electrode 30 by a fourth electrode extending between the first electrode and a second terminal of the capacitor 70. As shown in FIG. 4, the third and fourth electrodes may be provided by extending the frequency output electrode 52 and the first electrode 30 respectively in a direction transverse to the length y of the strip of graphene 20. The first and second sets of fingers 72, 74 then extend in a direction generally aligned with the length of the strip of graphene 20. As such, the capacitor 70 is provided generally adjacent to the first region 60 of the strip of graphene 20. Of course, in other embodiments, the strip of graphene may be arranged in different locations on the substrate 10.

In some embodiments, the capacitor 70 may be provided using a capacitor dielectric layer (not shown in FIG. 4). Such a capacitor 70 may comprise third and fourth electrodes connected to the frequency output electrode 52 and the first electrode 30 respectively, wherein the third and fourth electrodes are formed on the substrate such that they at least partially overlap, separated by the capacitor dielectric layer. As such, the capacitor may be formed on the substrate as a stack of layers: electrode, dielectric, electrode.

Next, a method 100 of forming the AC to DC current converter circuit of FIG. 4 will be explained. It will be appreciated that the following method may also be used to form the integrated frequency multiplier circuit 1 of FIG. 1. FIG. 5 shows a block diagram of the method 100.

In step 101, a graphene layer is deposited on a substrate using a chemical vapour process. For example, the method of WO 2017/029470 may be used to form the graphene layer as discussed above.

In step 102, the graphene layer is patterned. The patterning process may comprise the formation of a mask layer following by etching of the graphene as described above. The graphene layer is patterned to define a strip of graphene 20, the strip having a width x and a length y extending from a first end to a second end. When forming the AC to DC converter 2, the graphene layer may also be patterned to define the first and second sets of fingers 72, 74 as described above. As such, all the graphene layers for the frequency multiplier circuit 1/AC to DC converter 2 may be formed from the same graphene layer.

In step 103, the dielectric layer 40 is formed on the strip of graphene 20. The dielectric layer 40 may be formed, for example using a CVD or MOCVD process as discussed above. The dielectric layer 40 is formed on the strip of graphene wherein the dielectric layer extends across the width of the strip of graphene and along a portion of the length of the strip towards the second end. A lithographic technique may be used to form the dielectric layer 40 with the desired shape on the strip of graphene 40.

In step 104, the contacts for the circuit are formed. Step 104 comprises forming the first and second electrodes 30, 32 in electrical contact with the strip of graphene 20 at the first and second ends respectively 21, 22.

Step 104 also comprises forming the frequency input electrode 50 on the dielectric layer 40, the frequency input electrode 50 provided across the width x of the strip of graphene 20, wherein the frequency input electrode 50 is closer to the first end 21 of the strip of graphene than the second end 22. It will be appreciated that the formation of the frequency input electrode must be performed after the formation of the dielectric layer 40. Other contacts formed in step 104 may be performed at the same time as forming the frequency input electrode 50, or at a different time period, including before forming the dielectric layer 40.

Ste 104 further comprises forming the frequency output electrode 52 in electrical contact with the strip of graphene 20 at a location along the length of the strip of graphene 20 between the second electrode 32 and the frequency input electrode 50 and spaced apart from the second electrode 32.

Where the capacitor 70 is provided as part of AC to DC converter 2, third and fourth electrodes may be formed to connect the frequency output electrode 52 and the first electrode 30 to the capacitor 70.

The electrodes formed in step 104 may be formed in line with the deposition methods discussed in more detail above.

Thus, according to this disclosure an integrated frequency multiplier circuit 1 is provided. The active device of the integrated frequency multiplier circuit 1 comprises graphene. In particular, the active and passive components of the circuit are formed from a strip of graphene 20 having a defined length y and width x. The formation of the graphene strip having a precisely defined size (length y and width x) allows the properties of the frequency multiplier circuit to be tailored to the desired application.

Furthermore, it will be appreciated that integrating passive and active components using the strip of graphene provides for a circuit which is lightweight (the resistor and FET both comprising graphene) relative to frequency multiplier circuits formed from other semiconducting materials.

This disclosure also provides an AC to DC converter 2, which can be formed in an integrated manner similar to the integrated frequency multiplier circuit 1.

1. An integrated frequency multiplier circuit comprising:
a substrate;
a strip of graphene having a uniform width provided on the substrate, the strip having a width x and a length y extending from a first end to a second end;
first and second electrodes provided in electrical contact with the strip of graphene at the first and second ends respectively;
a dielectric layer provided on the strip of graphene, the dielectric layer provided across the width x of the strip of graphene
a frequency input electrode formed on the dielectric layer, the frequency input electrode provided across the width x of the strip of graphene, wherein the frequency input electrode is provided over the strip of graphene at a location closer to the first end of the strip of graphene than the second end;
a frequency output electrode provided in electrical contact with the strip of graphene at a location along the length of the strip of graphene between the second electrode and the frequency input electrode and spaced apart from the second electrode.

2. The integrated frequency multiplier circuit according to claim 1 wherein the frequency output electrode is equally spaced from the first and second electrodes along the strip of graphene.

3. The integrated frequency multiplier circuit according to claim 1, wherein
the graphene sheet has a sheet resistance in the range of 250 Ω/sq to 10 kΩ/sq.

4. The integrated frequency multiplier circuit according to claim 1, wherein
the first and second electrical contacts are each provided on the substrate adjacent to the strip of graphene such that each of the first and second electrical contacts are in direct contact with a respective edge of the strip of graphene.

5. The integrated frequency multiplier circuit according to claim 1, wherein
the substrate comprises a non-metallic surface on which the graphene strip is provided.

6. The integrated frequency multiplier circuit according to claim 1, wherein
the dielectric layer comprises an inorganic oxide, nitride, carbide, fluoride or sulphide, preferably alumina or silica.

7. The integrated frequency multiplier circuit according to claim 1, wherein
the length y of the strip of graphene is at least 5 mm and/or no greater than 20 mm; and/or
the width x of the strip of graphene is at least 1 mm and/or no greater than 10 mm.

8. The integrated frequency multiplier circuit according to claim 1, wherein
the location of the frequency output electrode on the strip of graphene and a sheet resistance of the graphene is provided such that a resistance of the strip of graphene between the frequency output electrode and the second electrode is at least 250 Ω and/or no greater than 50 kΩ.

9. The integrated frequency multiplier circuit according to claim 1, wherein
an aspect ratio of the length y of the strip of graphene to the width w of the strip of graphene is at least 0.5; and/or
the aspect ratio of the length y of the strip of graphene to the width w of the strip of graphene is no greater than 20.

10. The integrated frequency multiplier circuit according to claim 1, further comprising:
a resistance dielectric layer provided on the strip of graphene, the resistance dielectric layer provided across the width x of the strip of graphene and between the frequency output electrode and the second end of the strip of graphene; and
a variable resistance electrode provided on the resistance dielectric layer, the variable resistance dielectric layer provided across the width x of the strip of graphene.

11. The integrated frequency multiplier circuit according to claim 1 provided as part of an AC to DC current converter circuit, further comprising
a capacitor connected between the frequency output electrode and the first electrode formed at the first end of the graphene strip.

12. The integrated frequency multiplier circuit according to claim 11, wherein
the capacitor is formed on the substrate, and the AC to DC current converter circuit further comprises:
a third electrode extending between the frequency output electrode and a first terminal of the capacitor; and
a fourth electrode extending between the first electrode and a second terminal of the capacitor.

13. The integrated frequency multiplier circuit according to claim 12, further comprising:
a capacitor dielectric layer provided between the first terminal of the capacitor and the second terminal of the capacitor.

14. The integrated frequency multiplier circuit according to claim 11, wherein
the capacitor is a graphene capacitor.

15. The integrated frequency multiplier circuit according to claim 14, wherein
the graphene capacitor comprises:
a first set of graphene fingers provided on the substrate; and
a second set of graphene fingers provided on the substrate,
wherein the first and second sets of graphene fingers are provided on the substrate such that the first and second sets of graphene fingers are interdigitated.

16. A method of forming an integrated frequency multiplier circuit comprising: depositing a graphene layer on a substrate using a chemical vapour process;
patterning the graphene layer to define a strip of graphene, the strip having a width x and a length y extending from a first end to a second end;
forming first and second electrodes in electrical contact with the strip of graphene at the first and second ends respectively;
forming a dielectric layer on the strip of graphene, the dielectric layer extending across the width of the strip of graphene and along a portion of the length of the strip towards the second end;
forming a frequency input electrode on the dielectric layer, the frequency input electrode provided across the width x of the strip of graphene, wherein the frequency input electrode is closer to the first end of the strip of graphene than the second end; and
forming a frequency output electrode in electrical contact with the strip of graphene at a location along the length of the strip of graphene between the second electrode and the frequency input electrode and spaced apart from the second electrode.

17. A method of forming an AC to DC current converter circuit comprising: depositing a graphene layer on a substrate using a chemical vapour process;
patterning the graphene layer to define a strip of graphene, the strip having a width x and a length y extending from a first end to a second end;
forming first and second electrodes in electrical contact with the strip of graphene at the first and second ends respectively;
forming a dielectric layer on the strip of graphene, the dielectric layer extending across the width of the strip of graphene and along a portion of the length of the strip towards the second end;
forming a frequency input electrode on the dielectric layer, the frequency input electrode provided across the width x of the strip of graphene, wherein the frequency input electrode is closer to the first end of the strip of graphene than the second end;
forming a frequency output electrode in electrical contact with the strip of graphene at a location along the length of the strip of graphene between the second electrode and the frequency input electrode and spaced apart from the second electrode; and
providing a capacitor in electrical contact between the frequency output electrode and the first electrode formed at the first end of the graphene strip.

18. A method of forming an AC to DC current converter circuit according to claim 17, wherein
providing the capacitor comprises: and
depositing a further graphene layer on a substrate using a chemical vapour process
patterning the graphene layer to define a first set of graphene on the substrate and a second set of graphene fingers on the substrate, wherein the first and second sets of graphene fingers are interdigitated.

19. The integrated frequency multiplier circuit according to claim 1, wherein
the substrate comprises silicon (Si), silicon carbide (SiC), silicon nitride (Si₃N₄), silicon dioxide (SiO₂), sapphire (Al₂O₃), aluminium gallium oxide (AGO), hafnium dioxide (HfO₂), zirconium dioxide (ZrO₂), yttria-stabilised hafnia (YSH), yttria-stabilised zirconia (YSZ), magnesium aluminate (MgAl₂O₄), yttrium orthoaluminate (YAlO₃), strontium titanate (SrTiO₃), cerium oxide (Ce₂O₃), scandium oxide (Sc₂O₃), erbium oxide (Er₂O₃), magnesium difluoride (MgF₂), calcium difluoride (CaF₂), strontium difluoride (SrF₂), barium difluoride (BaF₂), scandium trifluoride (ScF₃), germanium (Ge), hexagonal boron nitride (h-BN), cubic boron nitride (c-BN) and/or a III/V semiconductor.

20. The integrated frequency multiplier circuit according to claim 1, wherein
the substrate comprises a III/V semiconductor selected from aluminium nitride (A1N) and gallium nitride (GaN).
